(19) United States
(12) Patent Application Publication
(10) Pub. No.: US 2017/0268936 A1
(43) Pub. Date: Sep. 21, 2017

(54) TEMPERATURE-MEASURING DEVICE, METHOD FOR MANUFACTURING THE DEVICE, AND SYSTEM FOR MEASURING THE POINT OF IMPACT INCORPORATED IN THE DEVICE

(71) Applicant: UNIVERSIDADE DE SANTIAGO DE COMPOSTELA, Santiago de Compostela (ES)

(72) Inventors: José Francisco RIVADULLA FERNÁNDEZ, Santiago de Compostela (ES); Tinh CONG BUI, Santiago de Compostela (ES)

(21) Appl. No.: 15/505,566

(22) PCT Filed: Aug. 17, 2015
(86) PCT No.: PCT/ES2015/070626

§ 371 Date: Feb. 21, 2017

(30) Foreign Application Priority Data
Aug. 21, 2014 (ES) P 201431244

(51) Int. Cl. G01K 7/36; G01L 5/00; H01F 1/147; H01F 41/22; H01B 1/02; H05K 3/14

(52) U.S. Cl. CPC G01K 7/36; H01B 1/02; H05K 3/14; H01F 1/14716; H01F 41/22; G01L 5/0052; B82Y 15/00

(57) ABSTRACT

A temperature measuring device, a process for manufacturing the device, and a system for measuring an impact point incorporating the device. According to one aspect, a temperature measuring device includes a thin film sheet made of magneto-metallic material such that, in use and the presence of an applied magnetic field, a change of temperature in one region of the sheet generates an electric voltage in the region, the generated electric voltage being readable through means for reading electric voltage corresponding to the region. According to another aspect, there is a process for manufacturing the device. According to yet another aspect, there is a system for measuring an impact point, of radiation or particles, incorporating the device.

### TECHNICAL FIELD OF THE INVENTION

The present invention relates to temperature measuring devices and to process of manufacturing temperature measuring devices.

### STATE OF THE ART

Numerous devices that allow temperature measurement are known in the state of the art, which are based on different physical phenomena. The vast majority of these systems aim to measure the ambient temperature of the system.

A temperature and humidity measurement system is shown in the US patent application US2014/105242. This system consists of nano-particles (carbon nanotubes) and a layer of non-conductive polymer.

An integrated circuit containing a conductive film, a plurality of electrodes and a polymer film is disclosed in U.S. Pat. No. 4,603,372. This system is used to measure the temperature and humidity of the environment.

All of these described temperature measuring devices have a complex configuration (electrodes, nano-particles, conductive and/or polymeric films, etc.) and also have insufficient temperature resolution as well as low stability and resolution.

Furthermore, there are also known systems which allow determining the position of the point of impact of a particle and/or radiation.

Thus, U.S. Pat. No. 4,898,471 discloses a particle detection system on surfaces with a particular pattern. This system is based on the application of a light beam and on the measurement of the signal reflected by the surface.

US patent application US2012/293192 discloses a photon and particle detection system based on the detection of the charge generated by the photon or particle when it strikes the system.

[Mayer et. to the. Nuclear Science Symposium, 1996. Conference Record., 1996 IEEE] discloses a system with sub-millimeter resolution for the measurement of radiation, in which its position is also determined, this system being based on the use of CdZnTe detectors.

Finally, [Lameres et.al, IEEE SENSORS 2010 Conference] discloses a radiation detection system which also allows indicating the position in which it impacts, based on the accumulation of charge produced by the incident radiation in the system.

In general, such detection systems and others known in the art require complex circuitry, which makes them costly and with a high susceptibility to failure. And the resolution they offer in the measurement, in the best case, is about a tenth of a degree.

### DESCRIPTION OF THE INVENTION

Therefore, there is a need for new temperature measuring devices and methods of manufacturing such temperature measuring devices which solve at least some of the above-mentioned problems. It is an object of the present invention to satisfy said need

According to a first aspect, this objective is achieved by providing a temperature measuring device comprising a thin film sheet of magnetic-metallic material, this sheet being formed by a plurality of regions and comprising each of these regions means for reading electric voltage in the region; so that, in operation and in the presence of an applied magnetic field, a variation of the temperature in one of the regions generates an electric voltage in the region (that is, causes a variation in the electric potential in the region), being readable this generated electric voltage through the means for reading electric voltage corresponding to the region.

In this way, a simple and efficient temperature measuring device (i.e., without requiring complex circuitry) is obtained. Moreover, it is capable of detecting small temperature variations at a very localized point, as the thin film sheet is divided into regions, each of which comprises means for reading or obtaining electrical voltage measurements when a temperature variation occurs in said region.

Furthermore, no special deposition of the film is required (it is adapted to the surface where the temperature is to be measured) and any type of ferromagnetic and metallic material can be used.

Moreover, it is a simple device, which can be manufactured using conventional techniques and at a reduced cost. Another advantage of the device object of the present invention is the spatial resolution that can be obtained for temperature measurement.

To obtain the regions in the sheet the sheet must be divided by a lithography process, a mask, etc., as will be described below.

Basically, the technical description of the operation of the device is based on the following premises.

The fundamental coefficients of charge and heat transfer in the electronic conductors can be described by a pair of kinetic equations in which the electric and thermal flows are linearly related to their corresponding conjugate forces: i.e., the electric field E and the thermal gradient ∇T. Due to the fact that the electric current J and the heat U can interact, a transport matrix in which the elements outside the diagonal are related through the Onsager-Kelvin reciprocal relations is defined. This is the basis of the thermoelectric, which provides the relationship between U and J, through the Peltier coefficient.

The different state density and Fermi velocities for electrons with up/down magnetic spin moment (the term “spin” being understood as an intrinsic moment of rotation of an elementary particle or of an atomic nucleus) characteristic of the magnetic-metallic materials population produces different conductivities for the opposite spin directions. When the spin relaxation time is greater than the relaxation time of the moment, the spin dependent part must be taken into account in the transport equations. Therefore, there is a Seebeck and Peltier coefficients dependent on the spin, based on the Onsager reciprocity. Furthermore, in magnetic conductors, the spin-orbit interaction introduces an anisotropic thermoelectric voltage, as a function of the angle Θ between the temperature gradient and the magnetization of the material M. These are the thermal counterparts (Onsager reciprocals) of anisotropic magnetoresistance (AMR) and the planar Hall effect (PHE). In the planar Nernst effect (PNE), the transverse voltage is related to the magnetization M and the angle Θ by:

S_{xy}=V_{xy}/∇Tₓ ∝/M|² sinΘcosΘ

wherein M and ∇T have components in the xy plane. However, a ∇Tz≠0 in a magnetic-metallic material will produce a potential difference V_{xy} due to the anomalous Nerst effect (ANE):

$${V}_{xy} = - {S}_{xx} ξ ( \hat{m} \times ∇ {T}_{z} )$$

wherein Sₓₓ is the linear Seebeck coefficient, \hat{m} is the unit vector of magnetization and ξ is the Nerst factor. Thus, a planar Nerst effect and an anomalous Nerst effect are produced on thin sheets of magnetic-metallic materials in the presence of magnetic fields.

As can be seen in the ANE equation, a system with a temperature difference proportional to its magnetization produces an electrical voltage perpendicular to both (see FIG. 2).

Therefore, the measurement of the electrical voltage in the region (i.e., the potential variation therein due to the temperature variation occurring therein) also makes it possible to determine the position (more precisely, the region of the thin film sheet) in which the temperature variation has occurred.

Since the Seebeck coefficient is in the order of microvolts per kelvin in ferromagnetic metals, and the Nernst coefficient typically varies between 0.1 and 0.5, temperature variations of the order of micro Kelvin can be solved, giving rise to tensions on the order of one microvolt fraction, which can be read with the corresponding reading means.

At this point it is important to note that the applied magnetic field may be parallel to the plane of the thin film or at least as parallel as possible to the orientation of the device and may have a value greater than 1900 A/m.

According to some examples, the thin film sheet comprised in the device may have a thickness in the range of 10 nm to 100 nm.

Furthermore, the magnetic-metallic material of the thin film sheet may be selected from:
a semi-metallic and magnetic material;
a perovskita-oxide material;
a permalloy type alloy;
a Ni—Cr alloy;
a metallic ferromagnetic element at room temperature.

The semi-metallic and magnetic material can be selected from La_{2/3}Sr_{1/3}MnO₃, La_{2/3}Ca_{1/3}MnO₃, Fe₃O₄, while the ferromagnetic and metallic element can be selected from Fe, Ni.

According to other examples, the means for reading the electric voltage may comprise, in each region, depositions of metallic material (for example metal contacts). These depositions allow the measurement of the electrical voltage generated in the sheet by a temperature variation produced therein (more precisely, in the region of the sheet in which this temperature variation occurs, which produces an electric voltage generation), i.e. a local variation in temperature in the thin film sheet generates a voltage which is measured in these depositions (they may have the shape, for example, of metal contacts). The depositions may form a regular array on the thin film sheet.

Thus, this means for reading the electric voltage may have, for each region, a configuration of, for example, a plurality of metal contacts (at least two), at which a conductive wire (for example make of copper) can be connected, which through their other ends can be connected to, for example, a nanovoltimeter or similar device to determine the variation of electric voltage in the region.

According to some examples, the depositions may be of a material selected from platinum, gold, palladium, silver, copper, aluminum. In addition, depositions may be punctual depositions and the separation between depositions of the same region may be in the range of microns to millimeters.

According to other examples, the temperature measuring device may further comprise a substrate on which the thin film sheet of magnetic-metallic material is settled.

According to further examples, there is also provided a system for measuring the point of impact of a particle which may comprise a temperature measuring device as described above; and a sheet of kinetic energy absorbing material, configured to transform the kinetic energy into a temperature variation (i.e., this sheet of kinetic energy absorbing material produces a local temperature variation in the temperature measuring device).

Basically, when a particle impact on the sheet of kinetic energy absorbing material, it transforms this energy into a temperature variation, which generates an electric voltage in the corresponding region of the thin film sheet which is in contact with the point of the sheet of kinetic energy absorbing material in which the particle has impacted. Through the corresponding means for reading electrical voltage (that present in the region) it is possible to read or obtain the voltage value produced by the impact of the particle. In addition, it is also possible to determine the point of impact of the particle on the thin film sheet (i.e. the region of the thin film sheet which has received the impact of the particle), since that region provides a voltage value different from zero, while the remaining regions of the thin film sheet have a zero voltage value. Therefore, it is possible to obtain a system that allows determining in a simple and cheap way the position in which a particle hits or impacts.

According to further examples, the present invention provides a system for measuring the impact point of a radiation beam comprising a temperature measuring device as described above; and a sheet of radiation absorbing material, configured to transform the energy of the radiation beam, into heat (i.e., this sheet of radiation absorbing material causes a local temperature variation in the temperature measurement device).

In the same way of the above described system, when a radiation beam impacts on the radiation absorbing sheet material, it transforms this energy into a temperature variation (e.g. in heat), which generates an electric voltage in the corresponding region of the thin film sheet which is in contact with the point of the sheet of radiation absorbing sheet material in which the radiation beam has impacted. Through the corresponding means for reading electrical voltage (that present in the region) it is possible to determine the voltage value produced due to the beam impact. Moreover, it is also possible to determine the point of impact of the beam on the sheet (i.e., the region of the sheet that has received the beam impact), since that region provides a voltage value different from zero, while the rest of regions of the sheet have a zero voltage value. Therefore, it is possible to obtain a system which allows a simple and inexpensive determination of the position in which a beam of radiation impacts.

At this point it is important to note that the radiation beam can be generated, for example, by a laser.

According to another aspect of the invention, it is provided a process for manufacturing a temperature measuring device comprising:
providing an aqueous solution comprising precursor cations and a polymer;
depositing by a deposition process the aqueous solution on a substrate;
subjecting the substrate to a heating process;
generating a plurality of metal depositions in the substrate.

According to some examples, the deposition process may be a physical vacuum deposition process, which may be selected from:
spin coating;
sputtering;
atomic layer deposition;
pulsed laser (PLD).

In addition, the step of generating a plurality of metal depositions in the substrate may comprise:
depositing metal on the substrate;
applying a mask to the substrate;
applying a lithography process to obtain a plurality of punctual metallic depositions on the substrate.

Punctual metallic depositions may be metal contacts, as discussed above.

The precursor cations which are comprised in the aqueous solution may be selected from La, Sr, Ca, Mn, Fe, Cr, Ni; and its concentration may be in the millimolar range.

Furthermore, the polymer may be selected from water-soluble polymers of PEI (polyethyleneimine) or chitosan type; and its concentration may be in the millimolar range.

According to some examples, the substrate on which the aqueous solution is deposited may be of a magnetic-metallic material, which may be selected from:
a semimetallic and magnetic material;
a perovskita-oxide material;
a permalloy type alloy;
a Ni—Cr alloy;
a metallic ferromagnetic element at room temperature

The magnetic semi-metallic material may be selected from La_{2/3}Sr_{1/3}MnO₃, La_{2/3}Ca_{1/3}MnO₃, Fe₃O₄, whereas the ferromagnetic metal element may be selected from Fe, Ni.

According to further examples, the step of subjecting the substrate to a heating process may comprise subjecting the substrate to a heating process in which the temperature is set in the range of 600° C. to 900° C.

According to still further examples, the depositions may be of a material selected from platinum, gold, palladium, silver, copper, aluminum.

Other advantages and features of embodiments of the invention will become apparent to the person skilled in the art from the description, or may be learned from the practice of the invention.

### BRIEF DESCRIPTION OF THE FIGURES

Particular embodiments of the present invention are described by way of non-limiting example, with reference to the accompanying drawings, in which

FIG. 1 shows examples of temperature measuring devices, according to the present description;

FIG. 2 shows a graphical representation of the variation of the voltage difference ∇V_{xy} generated by a thermal gradient as a function of the magnitude of the magnetic field H;

FIG. 3 shows a graphical representation of the variation of the voltage V generated by a temperature gradient by varying the applied magnetic field H.

### DETAILED DESCRIPTION OF THE INVENTION

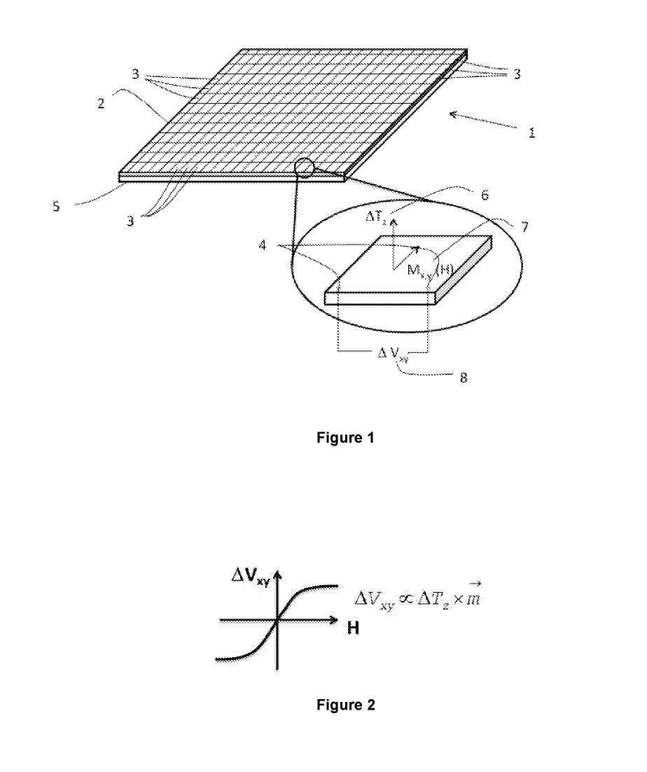

As can be seen in FIG. 1, according to some examples, a temperature measuring device 1 may comprise a thin film sheet 2 of magnetic-metallic material. This thin film sheet 2 may be formed of a plurality of regions 3, comprising each of these regions means for reading electric voltage 4 in the region. Thus, when the device 1 is in operation and in the presence of an applied magnetic field, a variation of the temperature in one of the regions 3 generates an electrical voltage (that is, it causes a variation in the electric potential in the region), being this generated electric voltage readable through the means for reading electric voltage corresponding to the region.

The magnetic-metallic material of the thin film sheet 2 may be selected from:
a semimetallic material;
a perovskita-oxide material;
a permalloy type alloy;
a Ni—Cr alloy;
a metallic ferromagnetic element at room temperature.

The magnetic semi-metallic material may be selected from La_{2/3}Sr_{1/3}MnO₃, La_{2/3}Ca_{1/3}MnO₃, Fe₃O₄, whereas the ferromagnetic metal element may be selected from Fe, Ni.

Furthermore, the thickness of the sheet 2 may be in the range of 10 nm to 100 nm.

According to some examples, the applied magnetic field may be parallel to the orientation of the device and may have a value greater than 1900 A/m.

The means for reading electric voltage 4 in the corresponding region may have the configuration of a plurality of electrical contacts (for example two), each of which may be connected to the end of a conductive (e.g. copper) wire. The other end of the wires may be connected to a nanovoltimeter or the like (not shown) in order to measure the voltage variation in the region.

Basically, FIG. 1 further shows the operation of the temperature measuring device 1 when forming part of a system for determining the impact point of a radiation beam or a particle, in which it is used a sheet 5 which transforms the kinetic energy of a particle in a temperature variation (in this case it may be a sheet of kinetic energy absorbing material) or the energy of radiation beam in heat (in this case it may be a sheet of radiation absorbing material), producing a gradient or a temperature variation 6. This temperature gradient 6 in the presence of a magnetic field 7 generates a voltage 8 which is measured and which allows to determine the point of impact of the radiation or the particle.

In some examples, a 35 nm thick layer of ferromagnetic and metallic oxide La_{2/3}Sr_{1/3}MnO₃ (LSMO) is deposited with side dimensions of 5 mm×5 mm. This layer is deposited by pulsed laser deposition (PLD) on a 0.5 mm thick monocrystalline SrTiO₃ (STO) substrate.

At one end of the LSMO film, a Pt line 4 mm long, 100 microns wide and 10 nm thick is deposited by evaporation. To determine or measure the voltage generated in response to the generation of a thermal gradient, the ends of the platinum line are connected by copper wires to a nanovoltimeter to determine the voltage variation, as described above.

The STO with the LSMO layer at its top is placed on a copper block with a ceramic electrical resistance inside it, which is used to vary the temperature and thus create a thermal gradient between the bottom and top of the LSMO film. In addition, the system is subjected to vacuum to a base pressure of 10−5 Torr, to avoid uncontrolled thermal gradients that can cause parasitic gradients which would contaminate the measurement.

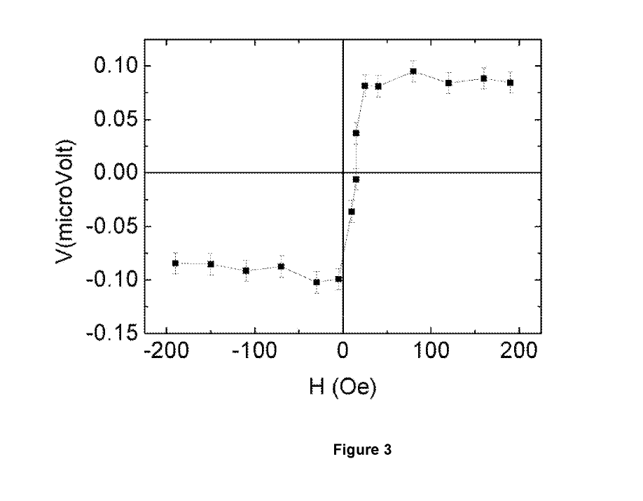

A current is applied to the resistor in the copper block in order to increase the temperature of the base and create a thermal gradient through the LSMO film. When very small power is dissipated (a few mW), a GaAs diode stuck to the copper base is not able to detect any variation of the temperature. However, as can be seen in FIG. 3, performing a magnetic field scanning a transverse voltage between the ends of the platinum strip, due to the Anomalous Nernst Effect (ANE), appears. This voltage changes sign when changing the magnetic field, as expected according to the ANE equation. Once the saturation magnetization of the LSMO system is reached, the read voltage is stable with the field. In addition, the voltage increases linearly with the thermal gradient through the LSMO layer. For the example shown, the estimated temperature variation is 2 micro Kelvin between the top and bottom of the 35 nm LSMO layer.

For reasons of completeness, various aspects of the present disclosure are set out in the following numbered clauses:
Clause 1. A temperature measuring device comprising:
   a thin film sheet of magneto-metallic material, being formed this sheet by a plurality of regions and comprising each of these regions means for reading electric voltage in the region, comprising this means metallic material depositions;
      so that, in operation and in the presence of an applied magnetic field, a temperature variation in one of the regions generates an electric voltage in the region, being readable this generated electric voltage through the means for reading electric voltage corresponding to the region.
Clause 2. The device, according to clause 1, wherein the sheet has a thickness comprised in the range 10 nm to 100 nm.
Clause 3. The device, according to clause 1, wherein the magneto-metallic material of the sheet is selected from:
   a semi-metallic and magnetic material;
   a perovskita-oxide material;
   a permalloy type alloy;
   a Ni—Cr alloy;
   a metallic ferromagnetic element at room temperature.
Clause 4. The device, according to clause 3, wherein the semi-metallic and magnetic material is selected from La_{2/3}Sr_{1/3}MnO₃, La_{2/3}Ca_{1/3}MnO₃, Fe₃O₄.
Clause 5. The device, according to clause 3, wherein the metallic ferromagnetic element is selected from Fe, Ni.
Clause 6. The device, according to clause 1, wherein the depositions are made of a material selected from platinum, gold, palladium, silver, cupper, aluminum.
Clause 7. The device, according to clause 1, wherein the depositions are punctual depositions.
Clause 8. The device, according to clause 6, wherein the separation between depositions of the same region is in the range from microns to millimeters.
Clause 9. The device, according to clause 1, wherein also comprises a substrate on which the thin film sheet of magneto-metallic material is settled.
Clause 10. A system for measuring an impact point comprising:
   a temperature measuring device according to clause 1;
   a sheet made of an absorbing material.
Clause 11. The system for measuring the impact point according to clause 10, wherein the impact point is of a particle or a radiation beam, and wherein:
   the sheet is made of a kinetic energy or a radiation absorbing material, configured to transform such kinetic energy into a temperature variation or radiation beam energy into heat.
Clause 12. A process for manufacturing a temperature measuring device wherein it comprises:
   providing an aqueous solution comprising precursor cations and a polymer;
   depositing by a deposition process the aqueous solution on a substrate;
   subjecting the substrate to a heating process;
   generating a plurality of metal depositions on the substrate.
Clause 13. The process, according to clause 12, wherein the deposition process is a physical vacuum deposition process.
Clause 14. The process, according to clause 13, wherein the physical vacuum deposition process is selected from:
   spin coating;
   sputtering;
   atomic layer deposition;
   pulsed laser (PLD).
Clause 15. The process, according to clause 12, wherein generating a plurality of metallic depositions in the substrate comprises:
   depositing metal on the substrate;
   applying a mask to the substrate;
   applying a lithography process to obtain a plurality of punctual metallic depositions on the substrate
Clause 16. The process, according to clause 12, wherein the precursor cations are selected from La, Sr, Ca, Mn, Fe, Cr, Ni.
Clause 17. The process, according to clause 12, wherein the polymer is selected from water soluble polymers of PEI (polyethyleneimine) or chitosan type.
Clause 18. The process, according to clause 12, wherein the cation concentration is in the millimolar range.
Clause 19. The process, according to clause 12, wherein the polymer concentration is in the millimolar range.
Clause 20. The process, according to clause 12, wherein the substrate is made of magneto-metallic material.
Clause 21. The process, according to clause 20, wherein the magneto-metallic material is selected from:
   a semimetallic and magnetic material;
   a perovskita-oxide material;
   a permalloy type alloy;
   a Ni—Cr alloy;
   a metallic ferromagnetic element at room temperature
Clause 22. The process, according to clause 21, wherein the semimetallic and magnetic material is selected from La_{2/3}Sr_{1/3}MnO₃, La_{2/3}Ca_{1/3}MnO₃, Fe₃O₄.
Clause 23. The process, according to clause 21, wherein the metallic ferromagnetic element is selected from Fe, Ni.
Clause 24. The process, according to clause 12, wherein subjecting the substrate to a heating process comprises subjecting the substrate to a heating process in which the temperature is set in the range of 600° C. to 900° C.
Clause 25. The process, according to clause 12, wherein the depositions are made of a material selected from platinum, gold, palladium, silver, cupper, aluminum.

Although only some particular embodiments and examples have been described here, one skilled in the art will appreciate that other alternative embodiments and/or uses are possible, as well as obvious modifications and equivalent elements. In addition, the present disclosure encompasses all possible combinations of the particular embodiments which have been described. Numerical signs relating to the drawings and placed in parentheses in a claim are only intended to increase the understanding of the claim, and should not be construed as limiting the scope of the protection of the claim. The scope of the present disclosure should not be limited to particular embodiments, but should be determined only by an appropriate reading of the appended claims.

1-25. (canceled)

26. A temperature measuring device comprising:
a thin film sheet of magneto-metallic material, the sheet being formed by a plurality of regions and comprising in each of these regions means for reading an electric voltage in the region, the means for reading electric voltage in the region comprising metallic material depositions;
so that, in operation and in the presence of an applied magnetic field, a temperature variation in one of the regions generates an electrical voltage in the region, the generated electric voltage being readable through the means for reading electric voltage corresponding to the region.

27. The device, according to claim 26, wherein the sheet has a thickness in the range of 10 nm to 100 nm.

28. The device, according to claim 26, wherein the magneto-metallic material of the sheet is selected from:
a semi-metallic and magnetic material;
a perovskita-oxide material;
a permalloy type alloy;
a Ni—Cr alloy; and
a metallic ferromagnetic element at room temperature.

29. The device, according to claim 28, wherein the semi-metallic and magnetic material is selected from La_{2/3}Sr_{1/3}MnO₃, La_{2/3}Ca_{1/3}MnO₃, and Fe₃O₄.

30. The device, according to claim 28, wherein the metallic ferromagnetic element is selected from Fe and Ni.

31. The device, according to claim 26, wherein the metallic material depositions are made of a material selected from platinum, gold, palladium, silver, copper, and aluminum.

32. The device, according to claim 26, further comprising a substrate upon which the thin film sheet of magneto-metallic material is settled.

33. A system for measuring an impact point, comprising:
a temperature measuring device according to claim 26;
a second sheet made of an absorbing material.

34. The system for measuring the impact point according to claim 33, wherein the impact point is a point of impact of a particle or a radiation beam, and wherein:
the second sheet is made of a kinetic energy or a radiation absorbing material configured to transform a kinetic energy of the particle into a temperature variation, or an energy of the radiation beam into heat.

35. A process for manufacturing a temperature measuring device, comprising:
providing an aqueous solution comprising precursor cations and a polymer;
depositing by a deposition process the aqueous solution on a substrate;
subjecting the substrate to a heating process; and
generating a plurality of metallic depositions on the substrate.

36. The process according to claim 35, wherein the deposition process is a physical vacuum deposition process.

37. The process according to claim 36, wherein the physical vacuum deposition process is selected from:
spin coating;
sputtering;
atomic layer deposition; and
pulsed laser (PLD).

38. The process according to claim 35, wherein generating a plurality of metallic depositions in the substrate comprises:
depositing metal on the substrate;
applying a mask to the substrate; and
applying a lithography process to obtain a plurality of punctual metallic depositions on the substrate.

39. The process according to claim 35, wherein the precursor cations are selected from La, Sr, Ca, Mn, Fe, Cr, and Ni.

40. The process according to claim 35, wherein the substrate is made of magneto-metallic material.

41. The process according to claim 40, wherein the magneto-metallic material is selected from:
a semimetallic and magnetic material;
a perovskita-oxide material;
a permalloy type alloy;
a Ni—Cr alloy; and
a metallic ferromagnetic element at room temperature

42. The process according to claim 41, wherein the semimetallic and magnetic material is selected from La_{2/3}Sr_{1/3}MnO₃, La_{2/3}Ca_{1/3}MnO₃, and Fe₃O₄.

43. The process according to claim 41, wherein the metallic ferromagnetic element is selected from Fe and Ni.

44. The process according to claim 40, wherein the subjecting the substrate to a heating process comprises subjecting the substrate to a heating process in which the temperature is set in the range of 600° C. to 900° C.

45. The process according to claim 40, wherein the depositions are made of a material selected from platinum, gold, palladium, silver, copper, and aluminum.
